(19) United States
(12) Patent Application Publication
(10) Pub. No.: US 2025/0341774 A1
(43) Pub. Date: Nov. 6, 2025

(54) MULTI-DEVICE CONTAINERS USEFUL WITH SEMICONDUCTOR PROCESSING DEVICES OF DIFFERENT DIMENSIONS, AND RELATED METHODS

(71) Applicant: ENTEGRIS, INC., Billerica, MA (US)

(72) Inventors: Huaping Wang, Eden Prairie, MN (US); Philip Stuart Glynn, Colorado Springs, CO (US); Anthony M. Tieben, Belle Plaine, MN (US); Russ V. Raschke, Chanhassen, MN (US); Brian Wiseman, Glencoe, MN (US); Tyler Monforton, Chaska, MN (US)

(21) Appl. No.: 19/200,457

(22) Filed: May 6, 2025

Related U.S. Application Data
(60) Provisional application No. 63/643,077, filed on May 6, 2024.
(60) Provisional application No. 63/750,763, filed on Jan. 28, 2025.
(60) Provisional application No. 63/755,929, filed on Feb. 7, 2025.
(60) Provisional application No. 63/766,755, filed on Mar. 4, 2025.

(51) Int. Cl. G03F 1/66; G03F 7/00; H01L 21/673

(52) U.S. Cl. CPC G03F 1/66; G03F 7/70741; H01L 21/67359

(57) ABSTRACT

Described are containers for storing, transporting, shipping, or processing fragile devices such as a reticles or an inner reticle pod, including, in particular, dual containment pods that are adapted to interchangeably contain either a reticle or an inner reticle pod.

### CROSS-REFERENCE TO RELATED APPLICATIONS

This application claims the benefit under 35 U.S.C. 119 of U.S. Provisional Patent Application No. 63/766,755 filed Mar. 4, 2025, U.S. Provisional Patent Application No. 63/755,929 filed Feb. 7, 2025, U.S. Provisional Patent Application No. 63/750,763 filed Jan. 28, 2025, and U.S. Provisional Patent Application No. 63/643,077 filed May 6, 2024, the disclosures of which are hereby incorporated herein by reference in their entirety.

### FIELD

The present disclosure relates to containers for storing, transporting, shipping, or processing fragile devices such as reticles and reticle pods. More particularly, the present disclosure relates to a dual containment pod that includes an outer pod adapted to interchangeably contain one of two different devices, such as an inner reticle pod or a reticle.

### BACKGROUND

One of the many process steps used in fabricating microelectronic and semiconductor devices is photolithography. Broadly, photolithography involves selectively exposing a specially-prepared substrate surface to a source of radiation using a patterned template to create a patterned surface layer on the substrate. The patterned template, referred to as a “mask” or “reticle,” is a flat, transparent or reflective plate that includes a pattern that is reproduced on the substrate surface by radiation that is passed through or reflected off the patterned template.

Photolithographic techniques use various wavelengths of radiation, including light in an ultraviolet range, light in a deep ultraviolet range, or light in an extreme ultraviolet range, referred to as extreme ultraviolet lithography (also known as EUV or EUVL). Extreme ultraviolet lithography is performed in an evacuated atmosphere (a low pressure environment or a “vacuum” environment) to minimize energy loss of EUV light from atmospheric gases. The reticle must therefore be moved between a cleanroom environment having an ambient (atmospheric) pressure condition, and the evacuated environment of a photolithography tool. Specialized devices referred to as “pods” or “reticle pods” are used to handle the reticle in a cleanroom environment and to transfer the reticle between the cleanroom environment and the evacuated environment of the photolithography tool.

Certain commercial reticle pod products have a “dual-pod” design that includes an inner reticle pod (a.k.a., “inner carrier” or “inner pod”) that holds and protects a reticle, and an outer reticle pod (a.k.a., “outer shell” or “outer pod”) that contains and transports the inner reticle pod. The outer pod includes a two-piece assembly that includes a lower “door” that supports the inner reticle pod, and an upper “dome” that covers the door to produce an outer pod interior that contains the inner reticle pod. The inner reticle pod can be removed from the outer pod to transfer the reticle between a cleanroom and an evacuated interior of a photolithography tool. The reticle can then be removed from the inner reticle pod and used in the evacuated photolithography tool.

The inner reticle pod includes a flat lower piece referred to as a base that provides support for the reticle, and a cover that can be placed over the base and the reticle to define an inner pod interior that contains the reticle. The inner reticle pod base includes reticle supports that support the reticle above an upper surface of the base. The inner reticle pod cover may optionally include one or more reticle retainers, each of which includes an inner retainer contact at the inner reticle pod interior that is adapted to engage a reticle held in the inner reticle pod interior to limit movement of the reticle within the inner reticle pod interior.

Conventional dual-pods include domes and doors that are adapted for the dome and the door to engage an inner reticle pod at the dome interior, and to limit or prevent movement of the inner reticle pod held at the outer pod interior. The door may include supports on an upper surface of the door that are configured to support an inner reticle pod above the upper surface of the door. The dome may include a set of dome clamps located at an underside of the dome interior, each of which contacts and applies pressure to a location at an exterior of the inner reticle pod cover when the dome is placed over the door.

### SUMMARY

The following describes containers or “pods” that are adapted for use during storage, transport, or handling of a reticle or an inner reticle pod during semiconductor processing. Example pods include those referred to as “dual containment” or “dual-pod” systems that use an outer pod that includes a door and a dome that are adapted to be assembled with the dome placed over the door to contain a semiconductor processing device within an outer dome interior.

Conventional outer pods are specifically adapted for use with a single type of semiconductor processing device having a single set of dimensions, surface features, and optional functional components such as a reticle retainer of an inner reticle pod held in the outer pod interior. Examples of conventional outer pods include a door that includes device supports arranged on the upper surface of the door at locations that are specific to provide support for only one single type of semiconductor processing device having a single set of dimensions and surface features, e.g., an inner reticle pod having a single set of dimensions and surface features. The door is specifically adapted to be used with one single dome design that includes dome pads or dome clamps that are arranged on the dome interior surface at locations to contact surfaces of the same single type of semiconductor processing device. Consequently, each outer pod is specifically designed to be useful with only one single type of semiconductor processing device that has a single set of dimensions and a single set of surfaces that will be contacted by the dome or the door. One single outer pod design having a combination of an outer pod door and an outer pod dome is required for use with every different design of a semiconductor processing device, and each outer pod design can be used with only the single type of semiconductor processing device.

However, semiconductor processing involves the use of many different semiconductor processing devices, e.g., reticles and inner reticle pods, each having different dimensions. The need for individual outer pods that are dedicated for use with just a single type of semiconductor processing device creates the need to have and to maintain different outer pods for each type of semiconductor processing device.

As opposed to conventional outer pods that can be used with just one specific semiconductor processing device, the present description relates to outer pods that are adapted or adaptable (“configurable”) for use with different semiconductor processing devices (referred to as “multi-device” containers, pods, or outer pods).

A door of a multi-device container, i.e., a multi-device door, includes (comprises) device supports that are useful to support two different types of semiconductor processing devices having different dimensions. The device supports may either be movable or non-movable. Movable device supports can be secured to, removed from, moved, or otherwise located and re-located at different locations on a multi-device door to alternately support one of two different semiconductor processing devices having different dimensions. Non-movable device supports are not adapted to be moved between different locations on the door, but are located on the door to allow the device supports to support one of two different semiconductor processing devices. An example door may contain one set of non-movable device supports and one set of movable device supports, e.g., one set of non-movable first device supports adapted to support a first semiconductor processing device having first dimensions and a second set of movable second device supports adapted to support a second semiconductor processing device having different dimensions.

Alternately or additionally, a multi-device container may include a dome that is adapted for use with two or more different semiconductor processing devices of different dimensions. Such a dome, i.e., a multi-device dome, includes dome clamps that are useful to contact two different semiconductor processing devices having different dimensions. The dome clamps may be movable or non-movable. Movable dome clamps can be moved and alternately located at different locations on a multi-device dome to alternately contact one of two different semiconductor processing devices having different dimensions. Non-movable dome clamps are not adapted to be moved between different locations on the dome, but are located on the dome to allow the dome clamps to alternately contact one of two different semiconductor processing devices having different dimensions. The dome may contain two sets of non-movable dome clamps, a first set of first dome clamps that are configured to contact a first semiconductor processing device having first dimensions and a second set of second dome clamps that are configured to contact a second semiconductor process having different dimensions.

In one aspect, the disclosure relates to a containment pod door adapted to alternately support a reticle or an inner reticle pod. The containment pod door includes a door upper surface, a set of reticle supports adapted to support a reticle above the door upper surface, and a set of pins adapted to support an inner reticle pod above the door upper surface.

In another aspect, the disclosure relates to a method of using a containment pod door capable of alternately supporting a reticle or an inner reticle pod. The containment pod door includes a door upper surface, a set of reticle supports adapted to support a reticle above the door upper surface, and a set of pins adapted to support an inner reticle pod above the door upper surface. The method includes: supporting the reticle on the set of reticle supports; removing the reticle from the set of reticle supports; and supporting the inner reticle pod on the set of pins.

### BRIEF DESCRIPTION OF THE DRAWINGS

FIGS. 1 and 2 show an example of a multi-device outer container that includes a multi-device door and a multi-device dome as described.

FIGS. 3A, 3B and 3C show an example of a multi-device door as described.

FIGS. 4A, 4B, 4C and 4D show an example of a multi-device dome as described.

FIGS. 5A and 5B show an example of a multi-device door as described.

All figures are schematic and not necessarily to scale.

### DETAILED DESCRIPTION

The present disclosure relates to containers, i.e., “pods” or “outer pods,” that are useful for containing, storing, or transporting a semiconductor processing device such as a photomask (reticle) or an inner reticle pod.

Example “pods” or “outer pods” include those referred to as “dual containment” or “dual-pod” systems that include a upper piece or “dome” and a lower piece or “door” that can be assembled by placing the dome over the door to define an outer pod interior that is adapted to contain a semiconductor processing device supported by the door. Conventional doors of dual containment pods include support surfaces (“device supports”) located on a door upper surface to support a semiconductor processing device. Conventional dual containment pod domes include contact surfaces (“pads” or, more generally, “dome clamps”) at an upper interior surface (“dome interior surface”) of the dome to contact and limit movement of a semiconductor processing device contained in the outer pod interior. The device supports of the door and the dome clamps of the dome are each arranged for the outer pod to contain one single type of semiconductor processing device, having one set of dimensions, but do not allow the outer pod to alternately contain two different types of semiconductor processing devices having different dimensions.

In contrast, as described herein, a dual containment pod, or a door of a dual containment pod, or a dome of a dual containment pod can be used to contain more than one single type of semiconductor processing device. The containment pod includes a basic external structure of a door and a dome, with internal structures that are adapted or adaptable (configurable) to interchangeably support and contain one of two different semiconductor processing devices. A dual containment pod door that can be used with two or more different types of semiconductor processing devices is referred to as a “multi-device door.” A dual containment pod dome that can be used with multiple different types of semiconductor processing devices is referred to as a “multi-device dome.” A dual containment pod that can be used with multiple different types of semiconductor processing devices is referred to as a “multi-device pod.” A multi-device door may be used with a multi-device dome, or with a dome that is adapted for use with only a single type of semiconductor processing device. A multi-device dome may be used with a multi-device door, or with a door that is adapted to support only a single type of semiconductor processing device.

A door of an outer pod as described includes a substantially flat upper door surface that may be square or rectangular, and that is adapted to alternately (individually) support two different semiconductor processing devices having two different sets of dimensions. The door may include movable device supports that may be secured at locations of the upper door surface in at least two different configurations, a first configuration to support a semiconductor processing device having first dimensions, such as a reticle, and a second configuration to support a semiconductor processing device having different (second) dimensions, such as an inner reticle pod. Alternately, a multi-device door may contain two sets of device supports that include one set of non-movable first device supports configured to support a first semiconductor processing device having first dimensions (e.g., an inner reticle pod) and a second set of movable second device supports that are configured to support a second semiconductor process having different dimensions (e.g., a reticle).

A semiconductor processing device such as a reticle or an inner reticle pod that is “supported” by device supports of a door is supported by the device supports with the semiconductor processing device being supported by the door in a manner that is adequate for safely holding, transporting, or storing the semiconductor processing device with the dome placed over the door and with dome clamps contacting the semiconductor processing device from above to maintain the position of the semiconductor processing device within an outer pod. For these purposes, a semiconductor processing device is considered to be supported by device supports of a door when the semiconductor processing device is held in place above the door upper surface with the semiconductor processing device contacting device supports of the door and being held in a flat, horizontal orientation above the door upper surface, with a bottom surface of the semiconductor processing device being oriented parallel to the door upper surface.

Device supports of a multi-device door can have any useful design that allows the device supports and the door to support two or more different types of semiconductor processing devices and may be movable or non-movable. Example device supports include those referred to a “reticle supports,” which are adapted to support a reticle above the door upper surface, and those referred to as “pins” (“KC” pins or “kinematic coupling pins”), which are adapted to support an inner reticle pod above the door upper surface. The reticle supports are structurally different from the pins, and the reticle supports are not adapted to support the inner reticle pod and the pins are not adapted to support the reticle. Example multi-device doors can include a first set of device supports that are reticle supports to support a reticle, and a second set of device supports that are pins to support an inner reticle pod.

Device supports that are movable are designed to be moved or placed at desired positions on a door upper surface by a user to allow movable device supports to be configured and re-configured on the door upper surface to alternately support one of two different types of semiconductor processing devices. Alternately, device supports may be non-movable, meaning that the device supports are not adapted to be moved to produce a different configuration of device supports.

Movable device supports are adapted and designed to be moved and positioned and re-positioned at different locations on an upper door surface to produce two or more different configurations of the device supports. The movable device supports may be removably attached to an upper door surface by any useful type of removable mechanical fastener, such as by a threaded engagement between a threaded device support and a threaded opening in the door upper surface. Alternately, a device support may have a threaded shaft that extends through a non-threaded opening in the door, and may be secured to the door by a threaded nut on the backside of the door. The door may have multiple sets of threaded or non-threaded openings, with each set of openings corresponding to a different configuration of device supports.

Other examples of movable device supports may be attached to the door and adapted to move between a location at which the movable device support is positioned to support a semiconductor processing device, and a different location at which the movable device support does not support a semiconductor processing device. In a first configuration, the movable device support can be positioned to place the device support at a location on the upper door surface to support a first semiconductor processing device having a first set of dimensions. In a second configuration, the movable device support can be positioned at a location on the upper door surface at which the movable device support does not support a semiconductor processing device, and also does not interfere with a semiconductor processing device being supported by the door.

A multi-device door can include a first set of movable device supports (e.g., pinss) that is adapted to be attached to the door upper surface in a first configuration to support a first semiconductor processing device (e.g. an inner reticle pod), and a second set of movable device supports (e.g., reticle supports) that is adapted be attached to the door upper surface in a second configuration to support a second semiconductor processing device of a different type (e.g., a reticle). To support the first semiconductor processing device, the first set of movable device supports is attached to the door upper surface in a first configuration, while the second set of movable devices supports is not attached to the door upper surface. To support the second semiconductor processing device, the second set of movable device supports is attached to the door upper surface in a second configuration, while the first set of movable devices supports is not attached to the door upper surface.

According to other examples, a multi-device door can include a first set of non-movable device supports on the door upper surface and a second set of movable device supports on the door upper surface, with each set of device supports being configured to support a semiconductor processing device of a different type. To support the first semiconductor processing device (e.g., an inner reticle pod), the first semiconductor processing device can be supported on the first set of non-movable device supports having a first height above the door upper surface, while the second set of movable device supports is positioned to not interfere with the first semiconductor processing device being supported by the first set of non-movable device supports, e.g., at a height that is below the first height. To support the second semiconductor processing device (e.g., a reticle), the device supports of the second set of movable device supports are moved to positions that are configured to support the second semiconductor processing device, e.g., to a height that is greater than the first height, while the first set of non-movable device supports remains attached to the door upper surface at positions (e.g., the first height) that do not interfere with the second semiconductor processing device being supported by the second set of movable device supports.

A dome of an outer pod is a generally rectangular-shaped (e.g., square-shaped) cover that can be placed over a door to define an outer pod interior adapted to contain a semiconductor processing device supported above an upper surface of the door. A dome includes a generally horizontally-extending top and four sidewalls that extend vertically down from the top to form a dome interior that is surrounded by the top and the sidewalls. The dome interior includes an upper interior surface on an underside interior surface of the dome.

A dome can include at least one and typically multiple clamps (referred to as “dome clamps”) located at the upper interior surface of the dome (a.k.a. the “dome interior surface”) and that are adapted to contact a semiconductor processing device located in the outer pod interior when the dome is placed over the door with the door supporting a semiconductor processing device. A dome clamp may be of a type referred to as a “pad” or a “clamp” that has a surface that contacts a semiconductor processing device located in the outer dome interior, with the dome placed over the door and a semiconductor processing device that is supported by the door. A dome clamp may be secured to the upper interior surface of the dome or may instead be secured to a dome plate that can be removably attached to the dome interior surface.

An outer pod dome as described may be a multi-device dome that is capable of being used with two different types of semiconductor processing devices. A multi-device dome is capable of being used with one type of semiconductor processing device using one configuration of dome clamps, and the same multi-device dome is capable of being used with a second type of semiconductor processing device using a second configuration of dome clamps. The dome clamps may be movable or non-movable in any manner described with reference to device supports of a multi-device door.

Dome clamps can be designed for different purposes and to contact different locations of a semiconductor processing device, depending on the type of the device. For outer pods that are adapted to contain an inner reticle pod or a reticle, a dome clamp may be adapted to contact a surface or edge of the inner reticle pod or reticle to prevent movement within the outer pod interior. For outer pods that are adapted to contain an inner reticle pod as the semiconductor processing device, a dome may include a dome clamp that is adapted to contact a cover of the inner reticle pod at a surface of the cover to prevent movement of the inner reticle pod within the outer pod interior and may additionally contain a dome clamp that is adapted to contact an outer retainer contact of a reticle retainer of the inner reticle pod cover.

Similar to a multi-device door that can include different design options of device supports that allow use of the multi-device door with different types of semiconductor processing devices, a multi-device dome may include different design options of movable or non-movable dome clamps. A dome clamp may be movable or non-movable, may be secured directly to a dome interior surface, or may be secured to a dome plate that is secured to a dome interior surface. Dome clamps that are movable are designed to be moved between or secured to different positions on a dome interior surface or a dome plate by a user, to allow multiple dome clamps to be configured and re-configured on the dome interior surface or dome plate to selectively and interchangeably configure or re-configure the dome clamps to contact one of two different types of semiconductor processing devices. Dome clamps that are “non-movable” include dome clamps do not need to be moved between locations of a first configuration and locations of a second configuration for the dome clamps to alternately contact one of two different semiconductor processing devices having different dimensions.

A multi-device dome that includes movable dome clamps, referred to as a “configurable multi-device dome,” can include a first set of movable dome clamps that can be configured to contact a first semiconductor processing device, and a second set of movable dome clamps that can be configured to contact a second semiconductor processing device of a different type. Alternately, dome clamps may be non-movable, meaning that the dome clamps are not adapted to be moved to produce a different dome clamp configuration.

Movable dome clamps are adapted and designed to be moved and positioned and re-positioned at different locations on a dome interior surface to produce two or more different dome clamp configurations. Movable dome clamps may be removably attached to a dome interior surface or to a dome plate by any useful type of removable mechanical fastener, such as by a threaded engagement between a threaded dome clamp and a threaded opening in the dome interior surface or dome plate, or by a dome clamp having a threaded shaft that extends through a non-threaded opening in a dome plate to be secured to the dome plate by a threaded nut on the backside of the dome plate. A dome interior surface or a dome plate may have multiple sets of threaded or non-threaded openings, with each set of openings corresponding to a different configuration of dome clamps. Alternatively, a multi-device dome may be used with two different dome plates that can be placed or replaced at the dome interior surface, with each dome plate having a different configuration of dome clamps. Alternatively, a multi-device dome may include a single dome plate that includes a first set of dome clamps adapted to contact a first type of semiconductor processing device on one side of the dome plate, and a second set of dome clamps adapted to contact a second type of semiconductor processing device on an opposite side of the dome plate.

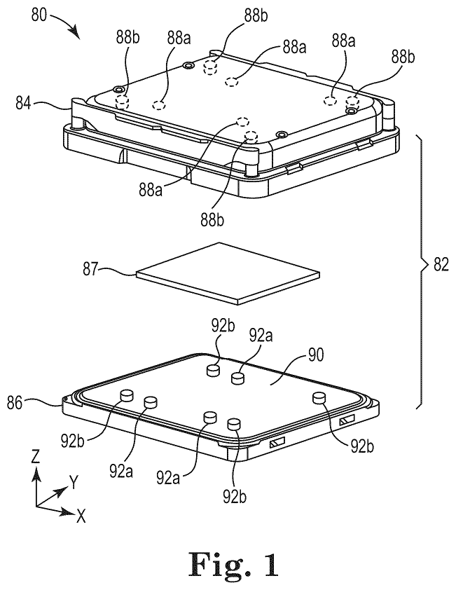

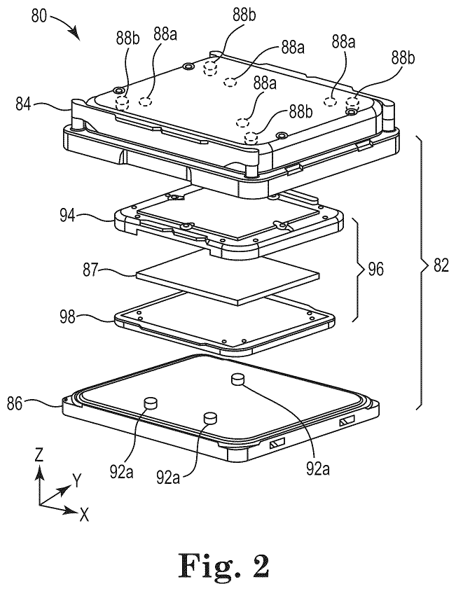

FIGS. 1 and 2 are exploded perspective views of an example multi-device dual containment pod 80. Dual containment pod 80 includes outer pod 82 having multi-device door 86 and multi-device dome 84.

Multi-device door 86 includes door upper surface 90 which includes two sets of device supports, 92a and 92b. Device supports 92a (KC pins) are non-movable and device supports 92b (reticle supports) are movable. Non-movable device supports 92a have a first height above door upper surface 90 at which device supports 92a are capable of supporting inner reticle pod 96 (see FIG. 2). Movable device supports 92b can be moved between a first location at which device supports 92b are positioned to support reticle 87 (see FIG. 1), wherein device supports 92b have a second height that is greater than the first height of inner device supports 92a, and a second location at which device supports 92b do not support either inner reticle pod 96 or reticle 87 and do not interfere with the support of inner reticle pod 96 by device supports 92a (see FIG. 2).

Multi-device dome 84 includes a dome inner surface (not visible), which includes multiple dome clamps 88, which, as illustrated, are non-movable. Dome clamps 88 include inner dome clamps 88a having a first height (a “height” dimension extends toward the semiconductor processing device), and outer dome clamps 88b having a different height that is greater than the height of inner dome clamps 88a. Inner dome clamps 88a are arranged in a configuration that is adapted to contact a first type of semiconductor processing device, which as illustrated in FIG. 2 is inner reticle pod 96, which includes inner reticle pod cover 94, base 98, and contains reticle 87 at an interior of inner reticle pod 96. Outer dome clamps 88b are arranged in a configuration that is adapted to contact a second type of semiconductor processing device, which as shown at FIG. 1 is reticle 87.

In use, multi-device dual containment pod 80 can alternately be used to contain either of reticle 87 or inner reticle pod 96 using the two different configurations of non-movable dome clamps 88 and non-movable device supports 92a or movable device supports 92b. As shown at FIG. 1, reticle 87 can be supported by movable device supports 92b, when positioned in a first configuration as shown at FIG. 1. Multi-device dome 84 can be lowered onto multi-device door 86, and outer dome clamps 88b contact surfaces of reticle 87, e.g., outer edge surfaces of reticle 87. After re-positioning movable device supports 92b to a second location or detaching movable device supports 92b from door upper surface 90 (see FIG. 2), inner reticle pod 96 can be supported by non-movable device supports 92a of multi-device door 86. Multi-device dome 84 can be lowered onto multi-device door 86, and outer dome clamps 88a will contact surfaces of inner reticle pod 96.

According to example methods, multi-device pod 80 can be used to support reticle 87 by placing reticle 87 onto movable device supports 92b of multi-device door 86 positioned at the first configuration as shown at FIG. 1, and by placing multi-device dome 84 over multi-device door 86 and reticle 87. When multi-device dome 84 is placed over multi-device door 86 and reticle 87, outer dome clamps 88b contact reticle 87. Reticle 87 can be transported or held in multi-device pod 80, then removed from multi-device pod 80. Movable device supports 92b can be re-positioned or removed as shown at FIG. 2, and multi-device pod 80 can be subsequently used to support inner reticle pod 96 by placing inner reticle pod 96 onto non-movable device supports 92a and placing multi-device dome 84 over multi-device door and inner reticle pod 96. When multi-device dome 84 is placed over multi-device door 86 and inner reticle pod 96, inner dome clamps 88a contact inner reticle pod 96. Inner reticle pod 96 can be transported or held in multi-device pod 80, then removed from multi-device pod 80.

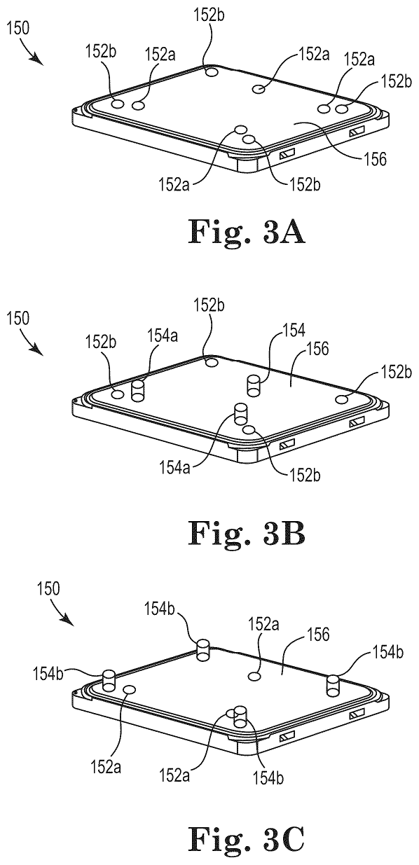

FIGS. 3A, 3B, and 3C show upper perspective views of another example of a multi-device door, that being multi-device door 150, which includes multiple configurations of openings 152 that can be used with movable device supports 154 to provide two or more alternate configurations of device supports 154 for multi-device door 150, each of which will support a semiconductor processing device having different dimensions. As shown at FIG. 3A, multi-device door 150 includes door upper surface 156 which includes openings 152, including a first configuration of inner openings 152a and a second configuration of outer openings 152b. Inner openings 152a can be used to secure a first set of movable device supports 154a according to a first configuration of movable device supports 154, for supporting a semiconductor processing device having a first set of dimensions. Movable device supports 154a may for example be KC pins adapted to support an inner reticle pod. Outer openings 152b can be used to secure a second set of movable device supports 154b according to a second configuration of device supports 154, for supporting a second semiconductor processing device having different dimensions. Movable device supports 154b may for example be reticle supports adapted to support a reticle.

In use, multi-device door 150 can alternately be used to support one of two different semiconductor processing devices each having different dimensions, such as a reticle (e.g., 87) or an inner reticle pod (e.g., 96). As shown at FIG. 3B, movable device supports 154a can be secured to inner openings 152a to form a first configuration of movable device support 154a adapted to support an inner reticle pod (e.g., inner reticle pod 96); outer openings 152b do not contain device supports. As shown at FIG. 3C, device supports 154a are removed from inner openings 152a and movable device supports 154b are secured to outer openings 152b to form a second configuration of movable device support 154b adapted to support a reticle (e.g., reticle 87).

According to example methods, movable device supports 154a can be secured to inner openings 152a to form a first configuration of movable device supports 154a adapted to support an inner reticle pod (e.g., inner reticle pod 96) while outer openings 152b do not contain a device support. See FIG. 3B. Multi-device door 150 can be used with a dome (e.g., a multi-device dome) that includes dome clamps configured to contact the inner reticle pod. Multi-device door 150 and a dome can be used with the dome placed over multi-device door 150 to contain the inner reticle pod, and the inner reticle pod can be transported or held in an outer pod assembly of multi-device door 150 and the dome. The dome can be removed from the assembled outer pod, and the inner reticle pod can be removed from the door. The multi-device door 150 can then be re-configured to include the second configuration of movable device supports 154b adapted to support a reticle (e.g., reticle 87) using openings 152b. The re-configured multi-device door 150, having the second configuration of movable device supports 154b, can be used with a dome (e.g., a multi-device dome) that includes a configuration of dome clamps adapted to contact the reticle. The multi-device door 150 and the dome can be used with the dome placed over multi-device door 150 to contain the reticle, and the reticle can be transported or held in an outer pod assembly of multi-device door 150 and the dome.

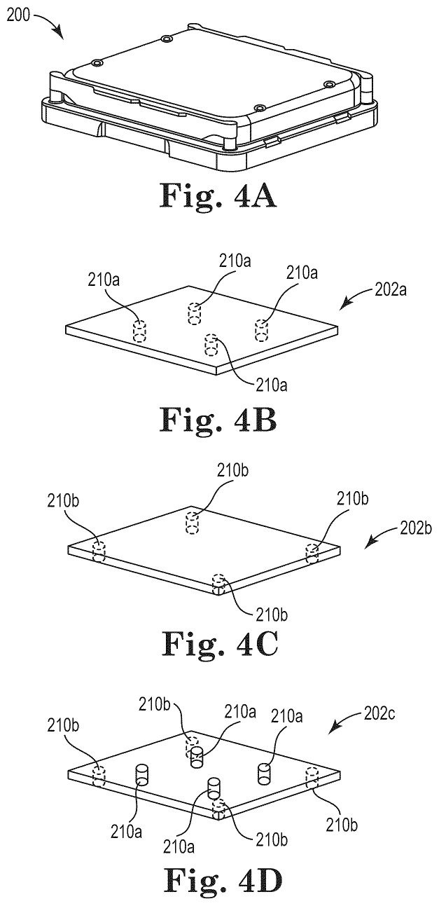

FIGS. 4A, 4B, 4C, and 4D show an upper perspective view of an example of a multi-device dome, that being multi-device dome 200. Multi-device dome 200 at FIG. 4A includes a dome interior surface (not visible) to which a dome plate can be secured. Multi-device dome 200 includes and can be used with multiple different dome plates, 202a, 202b, or 202c, each of which includes a different configuration of dome clamps 210 secured to the dome plate, and each of which can be selectively and alternatively secured to the dome interior surface.

FIG. 4B shows dome plate 202a, which includes dome clamps 210a arranged in a first configuration, e.g., to contact an inner reticle pod (e.g., inner reticle pod 96). FIG. 4C shows dome plate 202b, which includes dome clamps 210b arranged in a second configuration, e.g., to contact a reticle (e.g., reticle 87).

In use, one of dome plates 202a or 202b can be selectively secured to the dome interior surface of multi-device dome 200 to alternately provide one of two different configurations of dome clamps 210 on the dome interior surface. For example, as shown at FIG. 4B, dome clamps 210a of dome plate 202a can be arranged in a first configuration of dome clamps adapted to contact an inner reticle pod (e.g., inner reticle pod 96); dome plate 202a can be attached to dome interior surface to configure multi-device dome 200 to be used with the inner reticle pod. As shown at FIG. 4C, dome clamps 210b of dome plate 202b can be arranged in a second configuration of dome clamps adapted to contact a reticle (e.g., reticle 87); dome plate 202b can be attached to the dome interior surface to configure multi-device dome 200 to be used with the reticle.

According to example methods, dome plate 202a can be secured to the dome interior surface of dome 200 to provide a first configuration of dome clamps 210a at the dome interior surface. Multi-device dome 200 can be used with a door (e.g., a multi-device door) that includes a configuration of device supports adapted to support the inner reticle pod. Multi-device dome 200 and the door can be used with the multi-device dome 200 placed over the door to contain the inner reticle pod, and the inner reticle pod can be transported or held in an outer pod assembly of multi-device dome 200 and the door. Multi-device dome 200 can be removed from the assembled outer pod and the inner reticle pod can be removed from the door. The multi-device dome 200 can then be re-configured to include the second configuration of dome clamps 210b by removing dome plate 202a from the dome interior surface and securing dome plate 202b to the dome interior surface. The re-configured multi-device dome 200, having the second configuration of dome clamps 210 adapted to contact a reticle, can be used with a door (e.g., a multi-device door) that includes a configuration of device supports adapted to support the reticle. The multi-device dome 200 and the door can be used with the multi-device dome 200 placed over the door to contain the reticle, and the reticle can be transported or held in an outer pod assembly of multi-device dome 200 and the door.

In an alternate embodiment shown at FIG. 4D, dome plate 202c includes a first set of dome clamps 210a arranged in a first configuration on a first side of dome plate 202c, e.g., to contact an inner reticle pod (e.g., inner reticle pod 96), and also includes a second set of dome clamps 210b arranged in a second configuration on a second side of dome plate 202c, e.g., to contact a reticle (e.g., reticle 87).

In use, dome plate 202c can be secured to the dome interior surface of multi-device dome 200 to provide two alternate configurations of dome clamps 210 on the dome interior surface. In a first configuration, dome plate 202c may be attached to the dome interior surface with dome clamps 210a facing down to contact a first semiconductor processing device (e.g., inner reticle pod 96). Alternately, in a second configuration, dome plate 202c may instead be attached to the dome interior surface with dome clamps 210b facing down to contact a second semiconductor processing device (e.g., reticle 87).

According to example methods, dome plate 202c can be secured to the dome interior surface of dome 200 to provide a first configuration of dome clamps 210a at the dome interior surface facing downward to contact a first semiconductor device, e.g., inner reticle pod 96. Multi-device dome 200 can be used with a door (e.g., a multi-device door) that includes device supports adapted to support the inner reticle pod. Multi-device dome 200 and the door can be used with multi-device dome 200 placed over the door to contain the inner reticle pod, and the inner reticle pod can be transported or held in an outer pod assembly of multi-device dome 200 and the door. Multi-device dome 200 can then be removed from the assembled outer pod and the inner reticle pod can be removed from the door. Multi-device dome 200 can then be re-configured by flipping dome plate 202c and again securing dome plate 202c to the dome interior surface to place the second configuration of dome clamps 210b facing downward to contact a different semiconductor processing device, e.g., reticle 87. The re-configured multi-device dome 200, having the second configuration of dome clamps 210b adapted to contact a reticle, can be used with a door (e.g., a multi-device door) that includes device supports adapted to support the reticle. Multi-device dome 200 and the door can be used with the multi-device dome 200 placed over the door to contain the reticle, and the reticle can be transported or held in an outer pod assembly of multi-device some 200 and the door.

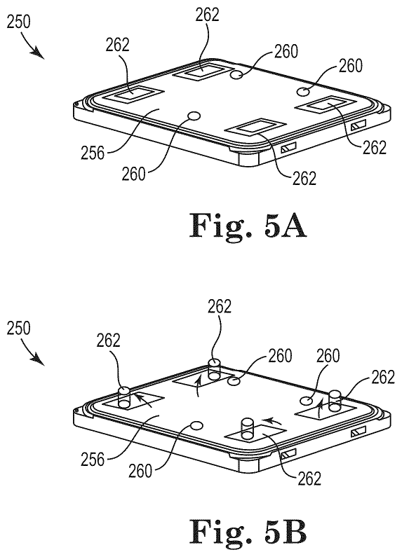

FIGS. 5A and 5B show upper perspective views of example of multi-device door 250 having a first set of non-movable devices supports 260 and a second set of movable (liftable) device supports 262. Non-movable device supports 260 and liftable device supports 252 provide two alternate configurations of device supports for multi-device door 150. Non-movable device supports 260 are KC pins adapted to support a first semiconductor processing device having first dimensions, such as an inner reticle pod, and liftable device supports 262 are reticle supports adapted to support a second semiconductor processing device having different dimensions, such as a reticle. With liftable device supports 262 in the lowered position (FIG. 5A), an inner reticle pod can be supported by non-movable device supports 260. Multi-device door 250 can be re-configured to support a second semiconductor processing device such as a reticle by lifting (see arrows) each of liftable device support 262 to a lifted position as shown at FIG. 5B. In the lifted position, liftable device supports 262 have a height that is greater than the height of non-movable device supports 260, and can support a reticle at a height above door upper surface 256 that is greater than the height of non-movable device supports 260.

1. A containment pod door adapted to alternately support a reticle or an inner reticle pod, the containment pod door comprising a door upper surface, a set of reticle supports adapted to support a reticle above the door upper surface, and a set of pins adapted to support an inner reticle pod above the door upper surface.

2. The containment pod door of claim 1, comprising:
a set of movable reticle supports adapted to support the reticle, and
a set of movable pins adapted to support the inner reticle pod.

3. The containment pod door of claim 1, comprising:
a set of movable reticle supports adapted to support the reticle, and
a set of non-movable pins adapted to support the inner reticle pod.

4. The containment pod door of claim 3, wherein the non-movable pins have a first height above the door upper surface and the movable reticle supports can be moved between a first location at which the movable reticle supports are below the first height and a second location at which the movable reticle supports are above the first height.

5. A containment pod comprising the containment pod door of claim 1 in combination with a dome, dome comprising: a first set of dome clamps adapted to contact the reticle supported by the door, and a second set of dome clamps adapted to contact the inner reticle pod supported by the door.

6. The containment pod of claim 5, wherein the multi-device dome comprises a dome plate that is removably attachable to a dome interior surface, the dome plate comprising:
a first side comprising a first set of dome clamps adapted to contact the inner reticle pod supported by the door, and
a second side comprising a second set of dome clamps adapted to contact the reticle supported by the door.

7. The containment pod of claim 6, wherein:
with the dome plate attached to a dome interior surface with the second set of dome clamps facing the dome interior surface, the first set of dome clamps is configured to contact the inner reticle pod supported by the door, and
with the dome plate attached to the dome interior surface with the first set of dome clamps facing the dome interior surface, the second set of dome clamps is configured to contact the reticle supported by the door.

8. The containment pod of claim 5, wherein the multi-device dome comprises a first dome plate that is removably attachable to a dome interior surface and a second dome plate that is removable attachable to the dome interior surface:
the first dome plate comprising a first set of dome clamps adapted to contact the inner reticle pod supported by the door, and
the second dome plate comprising a second set of dome clamps adapted to contact the reticle supported by the door.

9. The containment pod of claim 8, wherein:
with first the dome plate attached to a dome interior surface, the first set of dome clamps is configured to contact the inner reticle pod supported by the door, and
with the second dome plate attached to the dome interior surface, the second set of dome clamps is configured to contact the reticle supported by the door.

10. A method of using a containment pod door capable of alternately supporting a reticle or an inner reticle pod, the containment pod door comprising a door upper surface, a set of reticle supports adapted to support a reticle above the door upper surface, and a set of pins adapted to support an inner reticle pod above the door upper surface, the method comprising:
supporting the reticle on the set of reticle supports,
removing the reticle from the set of reticle supports, and
supporting the inner reticle pod on the set of pins.

11. The method of claim 10, wherein the containment pod door comprises:
a set of movable reticle supports adapted to support the reticle, and
a set of movable pins adapted to support the inner reticle pod, the method comprising:
securing the movable reticle supports to the door upper surface,
supporting the reticle on the reticle supports secured to the door upper surface,
removing the reticle from the reticle supports secured to the door upper surface,
removing the movable reticle supports from the door upper surface,
securing the movable pins to the door upper surface, and
supporting the inner reticle pod on the pins secured to the door upper surface.

12. The method of claim 10, wherein the containment pod door comprises:
a set of movable reticle supports adapted to support the reticle, and
a set of non-movable pins adapted to support the inner reticle pod.

13. The method of claim 12, wherein the non-movable pins have a first height above the door upper surface and the movable reticle supports can be moved between first locations at which the movable reticle supports are below the first height and second locations at which the movable reticle supports are above the first height.

14. The method of claim 13, comprising:
with the movable reticle supports at the first locations, supporting the inner reticle pod on the non-movable pins,
removing the inner reticle pod from the non-movable pins,
moving the movable reticle supports to the second locations, and
supporting the reticle on movable reticle supports in the second locations.

15. The method of any of claims 10 through 14, comprising placing a dome over the door, the dome comprising a set of dome clamps adapted to contact the reticle supported by the reticle supports, and a set of dome clamps adapted to contact the inner reticle pod supported by the pins.

16. The method of claim 15, wherein the dome comprises a dome plate that is removably attachable to a dome interior surface, the dome plate comprising:
a first side comprising a first set of dome clamps adapted to contact the inner reticle pod supported by the pins, and
a second side comprising a second set of dome clamps adapted to contact the reticle supported by the reticle supports,
the method comprising:
with the dome plate attached to the dome interior surface with the second set of dome clamps facing the dome interior surface, the first set of dome clamps contacts the inner reticle pod supported by the pins, and
with the dome plate attached to the dome interior surface with the first set of dome clamps facing the dome interior surface, the second set of dome clamps contacts the reticle pod supported by the reticle supports.

17. The method of claim 15, wherein the dome comprises a first dome plate that is removably attachable to a dome interior surface and a second dome plate that is removable attachable to the dome interior surface,
the first dome plate comprising a first set of dome clamps adapted to contact the inner reticle pod supported by the pins, and
the second dome plate comprising a second set of dome clamps adapted to contact the reticle supported by the reticle supports,
the method comprising:
with first the dome plate attached to the dome interior surface, the first set of dome clamps contacts the inner reticle pod supported by the pins, and
with the second dome plate attached to the dome interior surface, the second set of dome clamps contacts the reticle supported by the reticle supports.
